(19) United States
(12) Patent Application Publication
(10) Pub. No.: US 2015/0305196 A1
(43) Pub. Date: Oct. 22, 2015

(54) Water-cooled Cooling Apparatus Integrated to Load Devices

(71) Applicant: MISSION CRITICAL SOLUTIONS CORPORATION, Bellevue, WA (US)

(72) Inventors: Marco Saita, BUSNAGO (IT); ShihWei Sun, Bellevue, WA (US)

(73) Assignee: MISSION CRITICAL SOLUTIONS CORPORATION, Bellevue, WA (US)

(21) Appl. No.: 14/256,882

(22) Filed: Apr. 18, 2014

(51) Int. Cl. H05K 7/20; G06F 1/20

(52) U.S. Cl. CPC H05K 7/20172; H05K 7/20218; H05K 7/20745; H05K 7/2079; G06F 1/20

(57) ABSTRACT

Disclosed is a water-cooled cooling apparatus integrated to load devices comprising: a common cold airflow chamber, a common warm airflow tunnel, a cabinet group, a water-cooled cooling device, and a group of electrical fans, wherein the enclosed airflow space is surrounded by the water-cooled cooling device and the group of electrical fans. Accordingly, a high efficiency and continuous cooling effect is provided.

### FIELD OF THE INVENTION

The present invention relates to a cooling apparatus for a composite electronic facility room, and more particularly to a water-cooled cooling apparatus integrated to load devices.

### BACKGROUND OF THE INVENTION

In a conventional arrangement, electronic devices are housed in a facility room such as, but not limited to, computer room, server room, colocation room, switch room, etc. Part of functions of the facility room is to cool operational electronic devices. Normally there are air moving equipment galleries next to the facility room. These galleries may be a part of open facility room or they may be partitioned as separate rooms. These galleries house the cooling equipment that delivers cold airflow to the facility room. Normally the facility room is an open space. This open space maybe arranged to have open cold aisle way and open hot aisle way. Usually standard rack cabinets are placed in this open space or placed between open cold and hot aisle ways. One end of rack cabinets takes in cold air from the open space or from the open cold aisle way to cool the electronic devices inside the rack cabinets. The hot air is then discharged from rack cabinets to the same open space or to the open hot aisle way. Most hot air is then circulated back from this open space or from the open hot aisle way to the cooling equipment galleries. The air cooling is then processed by the cooling equipment such as CRAH (computer room air handler), CRAC (computer room air conditioner), or AHU (air handling unit) inside the galleries. Such open air circulation configuration requires fair amount of energy for fans inside the cooling equipment. From airflow perspective, the open configuration may not provide proactive air management to the rack cabinets either. Besides low effectiveness on energy usage and air management, the fans of the cooling equipment may not be supported by Uninterruptible Power Supply (UPS) system. In a power interruption event, the facility room cooling effectiveness is further compromised. If there is a UPS for the cooling equipment, due to fair amount of fan power requirement for this open air configuration, the UPS solution also needs to be generously sized to match overall fan power and redundancy requirements.

Overall, in environmental and energy conscious society, it is a positive thing to develop a more effective solution for either custom or standard rack cabinets to achieve same cooling function and high level of reliability. It is also an intriguing challenge to provide a highly efficient cooling apparatus for an electronic facility room with effective and reliable UPS solution for cooling the electronic load devices.

### SUMMARY OF THE INVENTION

Accordingly, an aspect of the present invention is for providing a water-cooled cooling apparatus integrated to load devices in which the air is flowing from a common cold airflow chamber to flow through the cabinet group to reach common warm airflow tunnel. In common warm airflow tunnel, air is warmed up because it picks up heat from the operational electronic devices inside the cabinet group. This hot air is efficiently guided through a water-cooled cooling device which cools down the hot air passing through it, and the air cooled by the cooling device is directly leaded to the enclosed airflow space. The air leaded to the enclosed airflow space is then moved by a group of electrical fans to the common cold-airflow chamber. It thus forms a tight air circulation path. This group of fans can be speed controlled and can be sized to move adequate air volume based on electronic device reliability requirements. These fans can also be, but do not have to, supported by various levels of UPS based on electronic device load density and reliability requirements. Accordingly, a cooling apparatus with high efficiency and high reliability is provided.

The present invention provides a water-cooled cooling apparatus integrated to load devices comprising: a common cold airflow chamber; a common warm airflow tunnel; a cabinet group provided with air intake front panels and air discharge back panels, the air intake front panels being for interfacing with the common cold airflow chamber for receiving cold airflow from the common cold airflow chamber, the air discharge back panels being for interfacing with the common warm airflow tunnel for expelling hot airflow from the cabinet group, wherein in the cabinet group, at least one load device is placed between the air intake front panels and the air discharge back panels; a water-cooled cooling device provided with an input-side being for connecting with the common warm airflow tunnel to receive hot airflow from the cabinet group, and an output-side being for expelling cold airflow from the cooling device to an enclosed airflow space; and a group of electrical fans connecting the enclosed airflow space for moving air from the enclosed airflow space to the common cold airflow chamber, wherein the enclosed airflow space is surrounded by the water-cooled cooling device and the group of electrical fans.

In a preferred embodiment of the present invention, the enclosed airflow space is an air transition space.

In a preferred embodiment of the present invention, cabinet groups are provided as multiple ones.

In a preferred embodiment of the present invention, the group of electrical fans has multiple fan members.

In a preferred embodiment of the present invention, an upper side of the enclosed airflow space is surrounded by the group of electrical fans and a peripheral side of the enclosed airflow space is surrounded by the water-cooled cooling device.

In a preferred embodiment of the present invention, the group of electrical fans is provided to move cold air from the enclosed airflow space to the common cold airflow chamber.

In a preferred embodiment of the present invention, the at least on load device is an electronic device.

In a preferred embodiment of the present invention, the water-cooled cooling device includes cooling coils.

In a preferred embodiment of the present invention, the common warm airflow tunnel is formed between the cooling coils and the cabinet group, and the input-side of the water-cooled cooling device is connected with the air discharge back panels of the cabinet group through the common warm airflow tunnel.

In a preferred embodiment of the present invention, the common warm airflow tunnel is surrounded by a ceiling, a floor, side walls and the cabinet group.

In a preferred embodiment of the present invention, the group of electrical fans is provided with UPS component and/or with redundant power distribution.

In a preferred embodiment of the present invention, the water-cooled cooling device is provided with cooling media chosen from water, glycol solution, and refrigerant.

By means of the present invention, it can provide a cooling apparatus integrated to load devices to protect load devices stored in the cabinet group from being overheated when a utility power outage happens or any specific numbers of electrical fan failure. Further, the water-cooled cooling device of the present invention use, but not limited to, water, which has the greatest specific heat, as the cooling media, so the water-cooled cooling device can effectively process heat exchange with lowest energy requirement. Moreover, the cooling surfaces formed by cooling coils of the water-cooled cooling device is very close to the cabinet group so that the hot airflow can be immediately transferred from the cabinet group to the cooling coils, through the enclosed airflow space, then through electrical fans and back to the common cold airflow chamber. Accordingly, the power requirement for the electrical fans can be dramatically lowered. Additionally, the mounting installation for the present invention is modular. It is scalable and flexible to fit into any open warehouse space with ease. It can dramatically reduce cost and installation schedule because each one of the apparatus can be built independently from another one or ship assembled for plug and play in place. Besides, various numbers of cabinets or cabinet groups can be deployed using partial module in accordance to different capacity needs or facility space limitations to thus achieve more customized options with similar economic form factor.

The structure and the technical means adopted by the present invention to achieve the above and other objects can be best understood by referring to the following detailed description of the preferred embodiments and the accompanying drawings.

### BRIEF DESCRIPTION OF THE DRAWINGS

FIG. 1 is a perspective view diagram illustrating the water-cooled cooling apparatus integrated to load devices of the first embodiment according to the present invention;

FIG. 2 is another perspective view diagram illustrating the water-cooled cooling apparatus integrated to load devices of the first embodiment according to the present invention;

FIG. 3 is another perspective view diagram illustrating the water-cooled cooling apparatus integrated to load devices of the first embodiment according to the present invention;

FIG. 4 is a sectional view diagram illustrating the water-cooled cooling apparatus integrated to load devices of the first embodiment according to the present invention;

FIG. 5 is a top view diagram illustrating the water-cooled cooling apparatus integrated to load devices of the second embodiment according to the present invention.

### DETAILED DESCRIPTION OF THE PREFERRED EMBODIMENTS

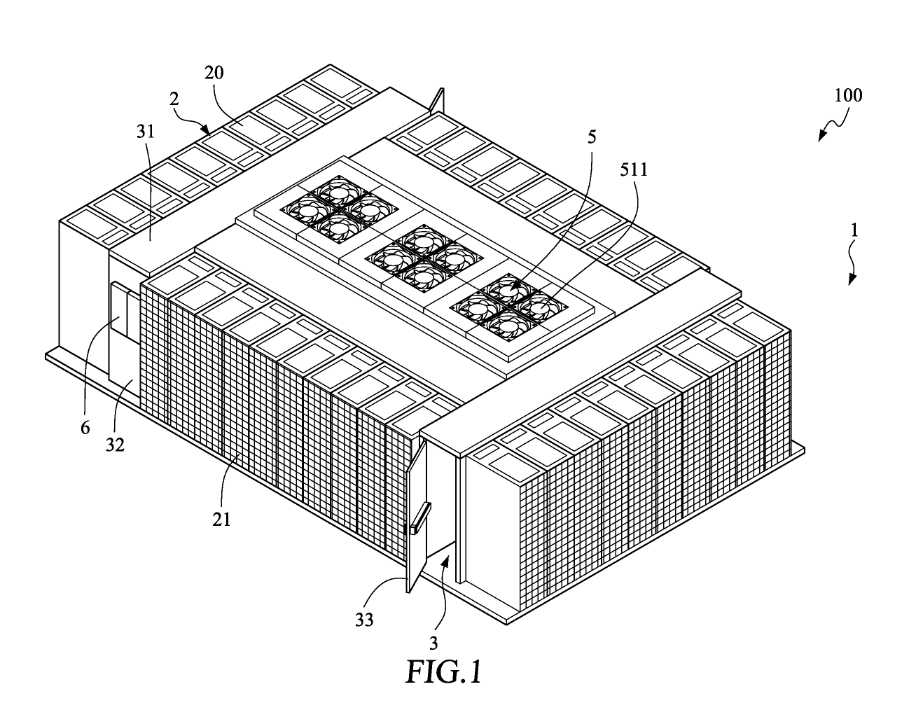

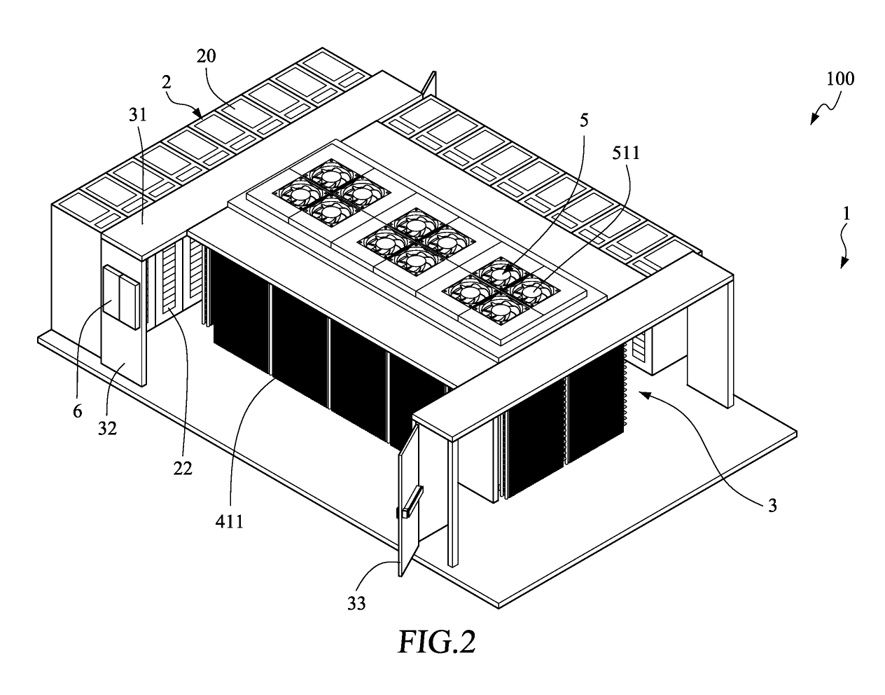

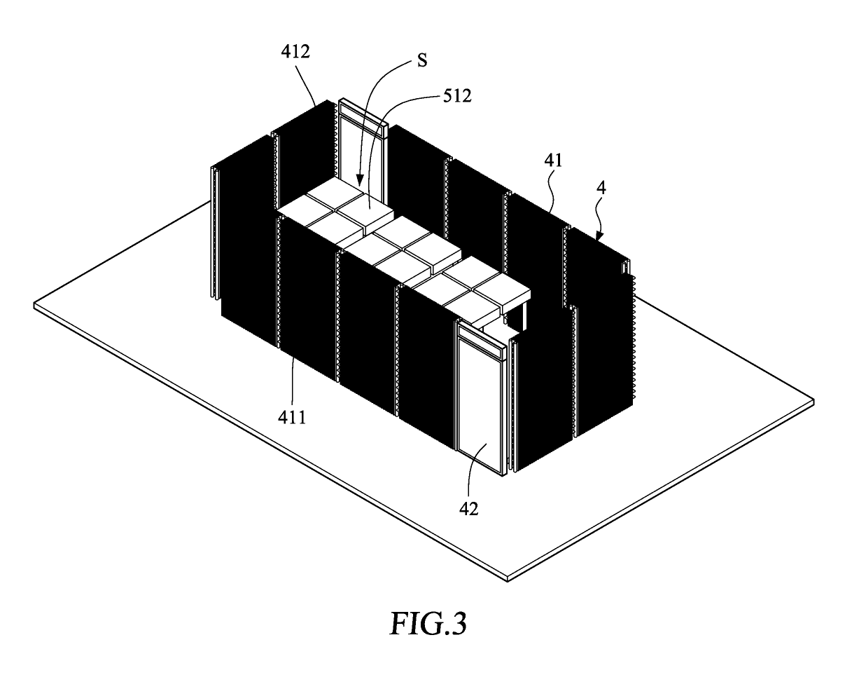

Refer to FIG. 1 to FIG. 4. A water-cooled cooling apparatus integrated to load devices 100 includes a common cold airflow chamber 1, multiple cabinet groups 2, a common warm airflow tunnel 3, a water-cooled cooling device 4, a group of electrical fans 5, and a power switchboard and/or control panel device 6, according to the first embodiment of the present invention.

The common cold airflow chamber 1 surrounds around the multiple cabinet groups 2 and is for providing cold air that is for air cooling. In the embodiment, the common cold airflow chamber 1 is provided with cold air which is cooled by the water-cooled cooling apparatus integrated to load devices 100.

In the embodiment, the water-cooled cooling apparatus integrated to load devices 100 is provided with four cabinet groups 2, and the four cabinet groups 2 are formed and arranged as a rectangle shape. The common cold airflow chamber 1 surrounds around the outside of the four cabinet groups 2, and the common warm airflow tunnel 3 is provided inside of the four cabinet groups 2. Each cabinet group 2 includes ten cabinets 20, and each ten cabinets 20 are closed arranged in a row to form one cabinet group 2. Each cabinet 20 may be a custom or a standard rack. Each cabinet group 2 is provided with air intake front panels 21 facing toward outside and with air discharge back panels 22 facing toward inside, and load devices 23 are placed between the air intake front panels 21 and the air discharge back panels 22. In the embodiment, the load devices 23 are electronic devices which generate heat load during operation. The air intake front panels 21 of each cabinet group 2 are interfaced with the common cold airflow chamber 1 for receiving airflow from the common cold airflow chamber 1, and the air discharge back panels 22 of each cabinet group 2 are interfaced with the common warm airflow tunnel 3 to expel the hot airflow from the cabinet group 2 to bring out the heat generated by load devices 23 during operation.

The common warm airflow tunnel 3 is surrounded by a ceiling 31, a side wall 32, an access door/panel 33, and the cabinet groups 2. Accordingly, the air from the common cold airflow chamber 1 is flowing through the cabinet groups 2 to the common warm airflow tunnel 3, and the access door/panel 33 is provided for access to the common warm airflow tunnel 3 and the enclosed airflow space S

The water-cooled cooling device 4 uses water, which has greatest specific heat, as cooling media. Of course, the present invention is no limited to this, and the water-cooled cooling device may use glycol solution or refrigerant as cooling media. The water-cooled cooling device 4 has cooling coils 41 and a water cooling circulator (not shown in the figures), and is provided to cool the air of the common warm airflow tunnel 3. The cooling coils 41 are provided inside of the four cabinet groups 2 to form a cooling wall which is formed and arranged as a rectangle shape. One side of the cooling coils 41 facing the common warm airflow tunnel 3 is an input-side 411, and the input-side 411 is connecting with the common warm airflow tunnel 3 to receive the hot airflow from the cabinet group 2. The other side of the cooling coils 41 is an output-side 412, and the output-side 412 is provided for expelling the cold airflow from the cooling device 4 to the enclosed airflow space S. The heat exchange operation of the water-cooled cooling device 4 is described as below. Hot air in the common warm airflow tunnel 3 is flowing to the cooling coils 41, and the heat in the hot air is transferred to the water of the cooling coils 41. Next, the water cooling circulator conveys the water to a cooling equipment, such as but not limited to a water cooled chiller, an air cooled chiller, a heat exchanger, a thermal storage device or various types of cooling towers, which removes heat and re-conveys the cooled water or cooling media back to the cooling device 4 thus provide a continuous cooling effect. Further, in other embodiment, a water-cooled cooling device of the present invention may additional provide with a function of continuous cooling system such as thermal storage device (not shown in the figures) to connect with the water-cooled cooling device in order to provide continuous cooling effect during various power failure conditions.

In the embodiment, the group of electrical fans 5 includes members of fan members 51. Each fan member 51 has a circulation fan 511 and these circulation fans are individually or in-group supported by UPS component 512 located anyplace inside the enclosed airflow space S. In other embodiment, these circulation fans may be provided with redundant power distribution or just with fan power distribution paths (not shown). These fan members 51 are at top of the enclosed airflow space S, but in other embodiment, these fan members 51 may be at bottom of the enclosed airflow space S. The enclosed airflow space S is airtight and surrounded by the fan members 51, the cooling coil 41 of the water-cooled cooling device 4, and a floor (fans at top) or a ceiling (fans at bottom with raised floor) to form an air transition space S where the air is transferred to the common cold airflow chamber 1. A passing door/panel 42 is proximately located with the cooling wall for the operator to pass between the common warm airflow tunnel 3 and the enclosed airflow space S. The group of electrical fans 5 moves the cold air of the enclosed airflow space S to the common cold airflow chamber 1, where each circulation fan 511 is connected with the UPS component 512 or with redundant power distribution to provide continuous airflow effect. Meanwhile the enclosed airflow space S is with relative negative pressure to the common warm airflow tunnel 3, so the hot air from the common warm air flow tunnel 3 is drawn through the water cooled cooling device and into the enclosed airflow space S. Similarly, the common warm airflow tunnel 3 is with relative negative pressure to the common cold airflow chamber 1, so the cold air from the common cold airflow chamber 1 is drawn through the cabinet group 2 and into the common warm airflow tunnel 3. Accordingly, all airflow is flowing by the operation of the group of electrical fans 5. Typically, the load devices 23 have built-in internal fans (not shown) to move air inside the cabinet group 2. The negative pressure of the embodiment can also support the electronic load devices which have no built-in internal fans.

In the embodiment, the power switchboard and/or control panel device 6 is installed on the side wall of the common warm airflow tunnel 3. As an option, they can also be installed at a remote location. When power or control redundancy is required, additional power switchboard and/or control panel device can be installed at another side wall. The power switchboard and/or control panel device 6 may include a power switchboard and/or a control panel. The power switchboard supplies power to the load devices 23 and to electrical fans 5. The control panel is for controlling, but do not have to, the water-cooled cooling device 4, the group of electrical fans 5, the UPS 512, the power switchboard and fire detection, suppression and protection system (not shown). Moreover, the cabinet groups 2 may further install with temperature sensors (not shown in the figures), and the power switchboard and/or control panel device 6 is able to display temperature of the airflow of each cabinet group 2 and/or all other relevant parameters of the embodiment for both local and/or remote monitor and control purpose.

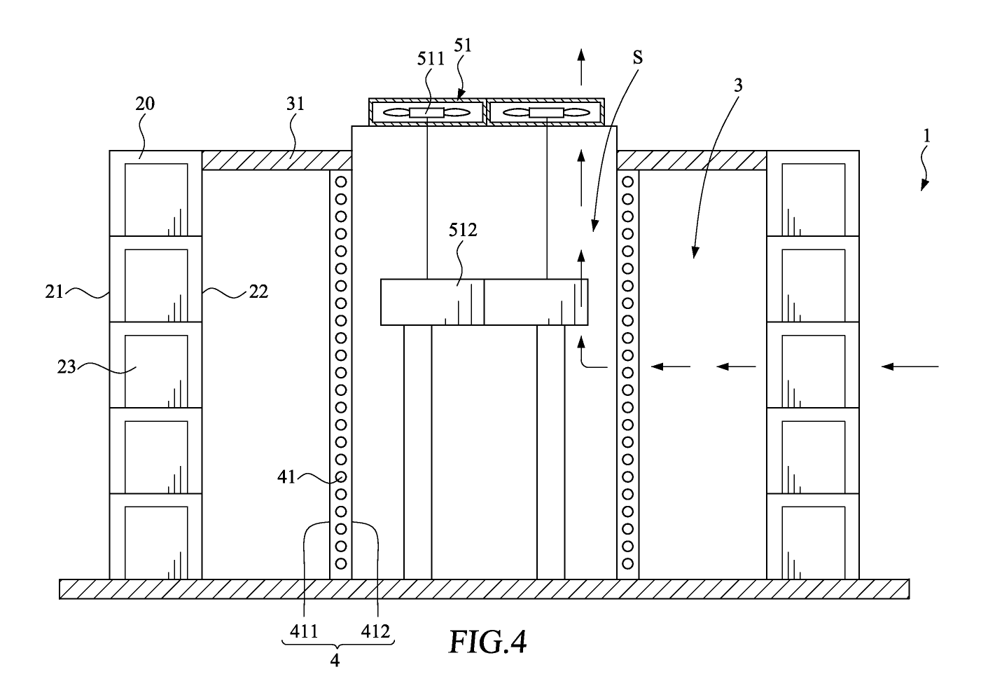

Refer to FIG. 4, the cold air flows from the common cold airflow chamber 1 to the air intake front panels 21 of the cabinet groups 2, and then air flows through the load devices 23 where the heat generated by the load devices is released and the airflow pick up the released heat become a hot air. This hot air is then discharged through the air discharge back panels 22 to the common warm airflow tunnel 3. Next, the hot air flows from the common warm airflow tunnel 3 to the input-side 411, and the hot air release the heat to the cooling coil 41 and becomes cold air. The cold air flows from the output-side 412 of the cooling coil 41 to the enclosed airflow space S. Finally, the group of electrical fans 5 moves the cold air from the enclosed airflow space S to the common cold airflow chamber 1.

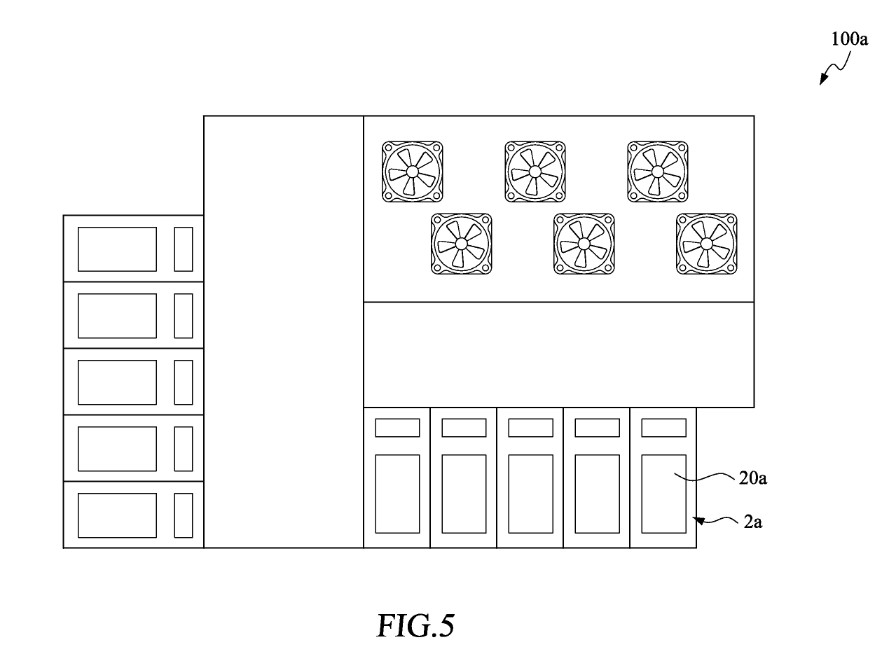

By means of the present invention with UPS, redundant power distribution and redundant fans, the group of electrical fans 5 can supply continuous airflow to prevent the risk of airflow stopping when utility power is not stable, or temporarily power interruptions, or any specific electrical fans are out of order. Accordingly, the load devices 23 of the cabinet groups 2 will not being overheated because of loss of airflow. Further, the water-cooled cooling device 4 or the cooling operation uses water, which has greatest specific heat, as cooling media. Therefore, the water cooled cooling device 4 can effectively process heat exchange with lowest energy requirement. Furthermore, the cooling surfaces formed by the cooling coils 41 of the water-cooled cooling device 4 is closely located to the cabinet groups 2, so that the hot air from the cabinet groups 2 is able to be immediately transfer through the cooling coil 41 to the enclose airflow space S, then through the group of electrical fans 5 and back to the common cold airflow chamber 1, and thus it minimizes the power consumption of the group electrical fans 5. And, any additional elements of an air-conditioning equipment is not required by means of the design that the cooling coil 41 of the water-cooled cooling device 4 is closely located to be surrounded by the cabinet groups 2. The water-cooled cooling apparatus integrated to load devices of the present invention is modular and flexible, thus can be built easily and manufactured quickly. Moreover, different number of cabinets and cabinet groups can be installed according to different demands. For example, referring to FIG. 5, it shows a water-cooled cooling apparatus integrated to load devices 100a in a second embodiment of the present invention only including two cabinet groups 2a which are arranged in shape of L. Each cabinet group 2a has five cabinets 20a. The water-cooled cooling apparatus integrated to load devices 100a includes in total ten cabinets 20, which is suitable for a situation that fewer cabinets is required, and is able to reduce fan members of the group of electrical fans for any other different situations. Of course, the present invention is not limited to this, and the number of cabinets, cabinet groups, and fans is able to be decreased or increased according to different requirements.

The above description should be considered as only the discussion of the preferred embodiments of the present invention. However, a person skilled in the art may make various modifications to the present invention. Those modifications still fall within the spirit and scope defined by the appended claims.

What is claimed is:

1. A water-cooled cooling apparatus integrated to load devices, comprising:
a common cold airflow chamber;
a common warm airflow tunnel;
a cabinet group provided with air intake front panels and air discharge back panels, the air intake front panels being for interfacing with the common cold airflow chamber for receiving cold airflow from the common cold airflow chamber, the air discharge back panels being for interfacing with the common warm airflow tunnel for expelling hot airflow from the cabinet group, wherein in the cabinet group, at least one load device is placed between the air intake front panels and the air discharge back panels;
a water-cooled cooling device provided with an input-side being for connecting with the common warm airflow tunnel to receive hot airflow from the cabinet group, and an output-side being for expelling cold airflow from the cooling device to an enclosed airflow space; and
a group of electrical fans connecting the enclosed airflow space for moving air from the enclosed airflow space to the common cold airflow chamber,
wherein the enclosed airflow space is surrounded by the water-cooled cooling device and the group of electrical fans.

2. The water-cooled cooling apparatus integrated to load devices as claimed in claim 1, wherein the enclosed airflow space is an air transition space.

3. The water-cooled cooling apparatus integrated to load devices as claimed in claim 1, wherein cabinet groups are provided as multiple ones.

4. The water-cooled cooling apparatus integrated to load devices as claimed in claim 1, wherein the group of electrical fans has multiple fan members.

5. The water-cooled cooling apparatus integrated to load devices as claimed in claim 1, wherein an upper side of the enclosed airflow space is surrounded by the group of electrical fans and a peripheral side of the enclosed airflow space is surrounded by the water-cooled cooling device.

6. The water-cooled cooling apparatus integrated to load devices as claimed in claim 1, wherein the group of electrical fans is provided to move cold air from the enclosed airflow space to the common cold airflow chamber.

7. The water-cooled cooling apparatus integrated to load devices as claimed in claim 1, wherein the at least on load device is an electronic device.

8. The water-cooled cooling apparatus integrated to load devices as claimed in claim 1, wherein the water-cooled cooling device includes cooling coils.

9. The water-cooled cooling apparatus integrated to load devices as claimed in claim 8, wherein the common warm airflow tunnel is formed between the cooling coils and the cabinet group, and the input-side of the water-cooled cooling device is connected with the air discharge back panels of the cabinet group through the common warm airflow tunnel.

10. The water-cooled cooling apparatus integrated to load devices as claimed in claim 1, wherein the common warm airflow tunnel is surrounded by a ceiling, a floor, side walls and the cabinet group.

11. The water-cooled cooling apparatus integrated to load devices as claimed in claim 1, wherein the group of electrical fans is provided with UPS component and/or with redundant power distribution.

12. The water-cooled cooling apparatus integrated to load devices as claimed in claim 1, wherein the water-cooled cooling device is provided with cooling media chosen from water, glycol solution, and refrigerant.
